(19) United States
(12) Patent Application Publication
(10) Pub. No.: US 2025/0012876 A1
(43) Pub. Date: Jan. 9, 2025

(54) MAGNETIC FIELD CURRENT SENSOR TO REDUCE STRAY MAGNETIC FIELDS

(71) Applicant: Allegro MicroSystems, LLC, Manchester, NH (US)

(72) Inventors: Rémy Lassalle-Balier, Bures sur Yvette (FR); Alexander Latham, Harvard, MA (US)

(73) Assignee: Allegro MicroSystems, LLC, Manchester, NH (US)

(21) Appl. No.: 18/893,088

(22) Filed: Sep. 23, 2024

Related U.S. Application Data
(62) Division of application No. 17/806,336, filed on Jun. 10, 2022, now Pat. No. 12,130,342.

(51) Int. Cl. G01R 33/09; G01R 15/20

(52) U.S. Cl. CPC G01R 33/098; G01R 15/205; G01R 33/091

(57) ABSTRACT

A magnetic field current sensor comprising: a conductor; magnetic field sensing elements including a first magnetic field sensing element generating a first signal, a second magnetic field sensing element generating a second signal, a third magnetic field sensing element generating a third signal, and a fourth magnetic field sensing element generating a fourth signal; circuitry that generates a difference signal indicative of twice the second signal less the first signal and less the fourth signal, wherein the second magnetic field sensing element is interleaved with the third magnetic field sensing element, wherein the second signal and the third signal are substantially equal, and wherein a distance between the first magnetic field sensing element and the second magnetic field sensing element is equal to a distance between the second magnetic field sensing element and the fourth magnetic field sensing element.

### CROSS-REFERENCE TO RELATED APPLICATIONS

This application is a divisional of and claims priority to U.S. patent application Ser. No. 17/806,336 filed on Jun. 10, 2022, the entire contents of which are hereby incorporated herein by reference.

### BACKGROUND

Magnetic field sensors are used in a variety of applications, including, but not limited to, an angle sensor that senses an angle of a direction of a magnetic field; a current sensor that senses a magnetic field generated by a current carried by a current-carrying conductor; a magnetic switch that senses the proximity of a ferromagnetic object; a rotation detector that senses passing ferromagnetic articles, for example, magnetic domains of a ring magnet or a ferromagnetic target (e.g., gear teeth) where the magnetic field sensor is used in combination with a back-biased or other magnet; a magnetic field sensor that senses a magnetic field density of a magnetic field, a linear sensor that senses a position of a ferromagnetic target; and so forth.

A magnetic field sensor may include a magnetic field sensing element. The magnetic field sensing element is used to describe a variety of electronic elements that can sense a magnetic field. The magnetic field sensing element can be, but is not limited to, a Hall effect element, a magnetoresistance element, or a magnetotransistor. As is known, there are different types of Hall effect elements, for example, a planar Hall element, a vertical Hall element, and a Circular Vertical Hall (CVH) element. There are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

### SUMMARY

According to aspects of the disclosure, a magnetic field current sensor is provided comprising: a conductor including a first turn, a second turn, and a third turn; planar Hall elements including: (i) a first planar Hall element generating a first signal, the first planar Hall element being disposed directly above or below a first region that is partially enclosed by the first turn, (ii) a second planar Hall element generating a second signal, the second planar Hall element being disposed directly above or below a second region that is partially enclosed by the second turn, (iii) a third planar Hall element generating a third signal, the third planar Hall element being disposed directly above or below the second region that is partially enclosed by the second turn, and (iv) a fourth planar Hall element generating a fourth signal, the fourth planar Hall element being disposed directly above or below a third region that is partially enclosed by the third turn; and circuitry that generates a difference signal indicative of twice the second signal less the first signal and less the fourth signal, wherein the second planar Hall element is interleaved with the third planar Hall element, wherein the second signal and the third signal are substantially equal, wherein the first planar Hall element, the second planar Hall element, the third planar Hall element and the fourth planar Hall element are in a first plane, and wherein a distance between the first planar Hall element and the second planar Hall element is equal to a distance between the second planar Hall element and the fourth planar Hall element.

According to aspects of the disclosure, a magnetic field current sensor is provided comprising: a two-turn conductor including a first turn and a second turn, vertical Hall elements including: (i) a first vertical Hall element generating a first signal, the first vertical Hall element being disposed directly above or below a first portion of the conductor that is part of the first turn only, (ii) a second vertical Hall element generating a second signal, the second vertical Hall element being disposed directly above or below a second portion of the conductor that is part of both the first turn and the second turn, (iii) a third vertical Hall element generating a third signal, the third vertical Hall element being disposed directly above or below the second portion of the conductor, and (iv) a fourth vertical Hall element generating a fourth signal, the fourth vertical Hall element being disposed directly above or below a fourth portion of the conductor that is part of the second turn only; and circuitry that generates a difference signal indicative of twice the second signal less the first signal and less the fourth signal, wherein the second vertical Hall element is interleaved with the third vertical Hall element, wherein the second signal and the third signal are substantially equal, wherein the first vertical Hall element, the second vertical Hall element, the third vertical Hall element and the fourth vertical Hall element are in a first plane, and wherein a distance between the first vertical Hall element and the second vertical Hall element is equal to a distance between the second vertical Hall element and the fourth vertical Hall element.

According to aspects of the disclosure, a magnetic field current sensor is provided comprising: a conductor; magnetic field sensing elements including a first magnetic field sensing element generating a first signal, a second magnetic field sensing element generating a second signal, a third magnetic field sensing element generating a third signal, and a fourth magnetic field sensing element generating a fourth signal; circuitry that generates a difference signal indicative of twice the second signal less the first signal and less the fourth signal, wherein the second magnetic field sensing element is interleaved with the third magnetic field sensing element, wherein the second signal and the third signal are substantially equal, and wherein a distance between the first magnetic field sensing element and the second magnetic field sensing element is equal to a distance between the second magnetic field sensing element and the fourth magnetic field sensing element.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1A is a block diagram of an example of a tunneling magnetoresistance (TMR) element;

FIG. 1B is a diagram of an example of a free layer having a magnetic vortex that includes a core in the center of the free layer;

FIG. 1C is a diagram of an example of a free layer having homogenous magnetization directions;

FIG. 1D is diagram of an example of a free layer influenced by an external magnetic field causing a magnetic vortex to be away from the center of a free layer;

FIG. 1E is diagram of an example of a free layer influenced by an external magnetic field to have almost homogenous magnetization directions;

FIG. 1F is diagram of another example of a free layer being influenced by an external magnetic field causing a magnetic vortex to be away from the center of a free layer;

FIG. 1G is diagram of another example free layer being influenced by an external magnetic field to have almost homogenous magnetization directions;

FIG. 2 is graph of a response signal versus magnetic field for a tunneling magnetoresistance element (TMR) having the magnetic vortex in the free layer;

FIG. 3 is a block diagram of an example of an annihilation detector circuit;

FIGS. 4A and 4B are graphs depicting examples of outputs of the annihilation detector;

FIG. 5A is a diagram of an example of current sensor configuration including a conductor and TMR elements having magnetic vortices;

FIG. 5B is an example of an annihilation bridge using the TMR elements in FIG. 5A;

FIG. 5C is an example of a current bridge using the TMR elements in FIG. 5A;

FIG. 6A is a diagram of an example of current sensor configuration including a conductor and TMR elements having two different pillar diameters and having magnetic vortices;

FIG. 6B is a diagram of an example of a bridge for TMR elements in FIG. 6A having a smaller diameter pillar;

FIG. 6C is a diagram of an example of a bridge for TMR elements in FIG. 6A having a larger diameter pillar;

FIG. 6D is a graph of an example of outputs for the bridges in FIGS. 6B and 6C;

FIG. 7A is an example of a current sensor configuration with a conductor and TMR elements having magnetic vortices;

FIG. 7B is an example of a current bridge using the TMR elements of FIG. 7A;

FIG. 8A is a diagram of another example of current sensor configuration including a conductor and TMR elements having magnetic vortices;

FIG. 8B is a diagram of a bridge using the TMR elements in FIG. 8A;

FIG. 8C is a diagram of an example of a bridge;

FIG. 9 is graph depicting a residual signal due to a nearby current line using a traditional differential current sensor configuration and the current sensor configuration of FIG. 8A;

FIG. 10A is an example of a current sensor configuration including a conductor and vertical Hall elements;

FIG. 10B is an example of a circuit to condition signals from the vertical Hall elements of FIG. 10A;

FIG. 11A is an example of a current sensor configuration including a conductor and planar Hall elements; and

FIG. 11B is an example of a circuit to condition signals from the planar Hall elements of FIG. 11A.

### DETAIL DESCRIPTION

Described herein are techniques to fabricate a current sensor that reduces the impact of stray magnetic fields. In one example, a current sensor includes an annihilation detector circuit and includes magnetoresistance elements that have a magnetic vortex in a free layer. In another example, a current sensor includes magnetoresistance elements that have at least two different pillar diameters and have a magnetic vortex in a free layer. In a further example, a current sensor includes magnetoresistance elements that have a magnetic vortex in a free layer and have some magnetoresistance elements that have reference directions that are 180° from other magnetoresistance elements. In a still further example, magnetic field sensing elements such as a planar Hall element, vertical Hall elements and magnetoresistance elements may be used in certain configurations in a current sensor to reduce gradient stray magnetic field effects and common mode stray magnetic field effects.

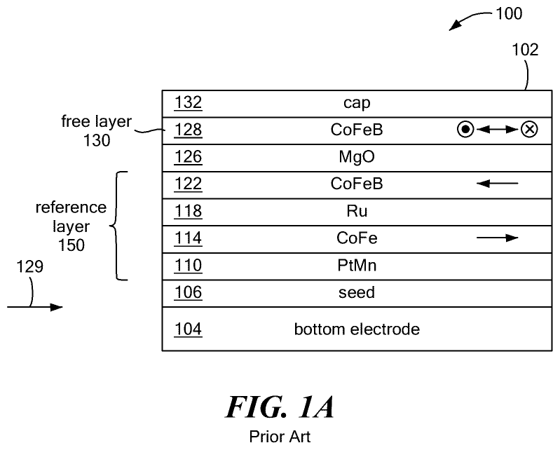

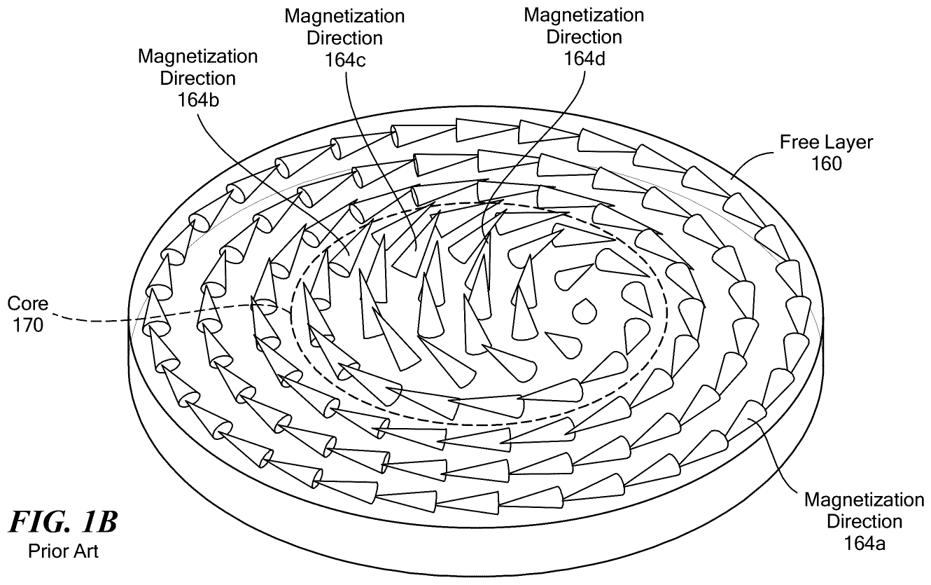

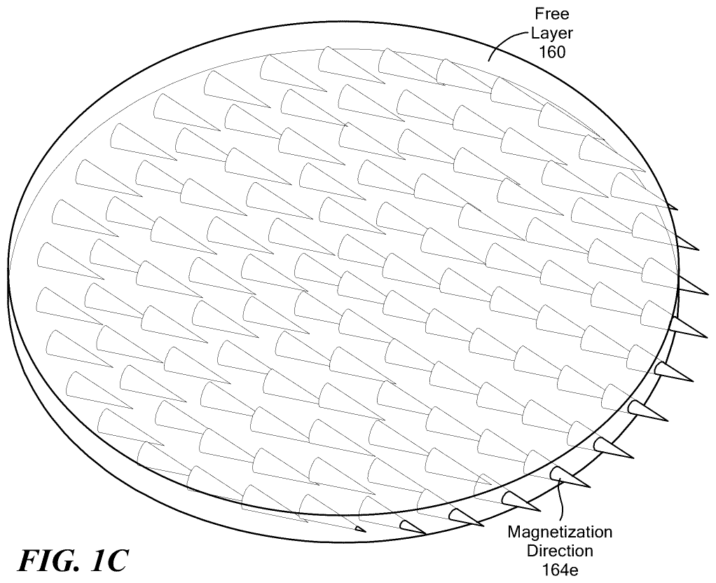

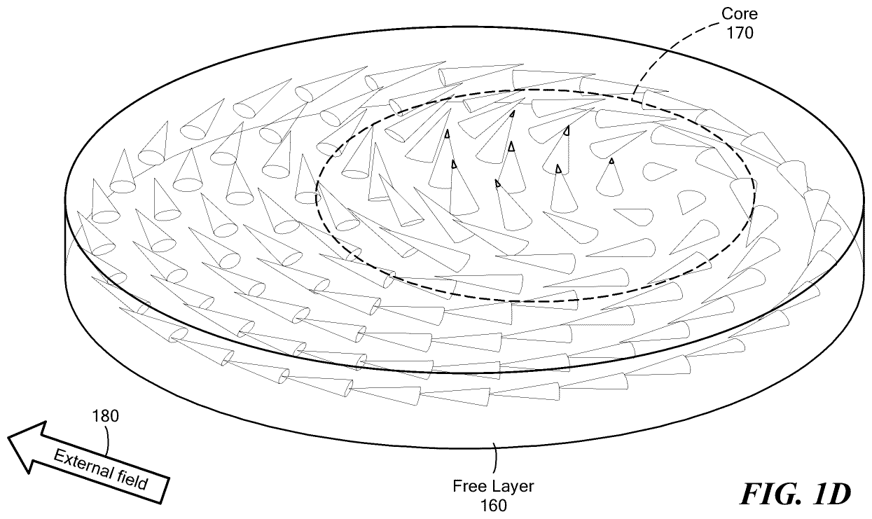

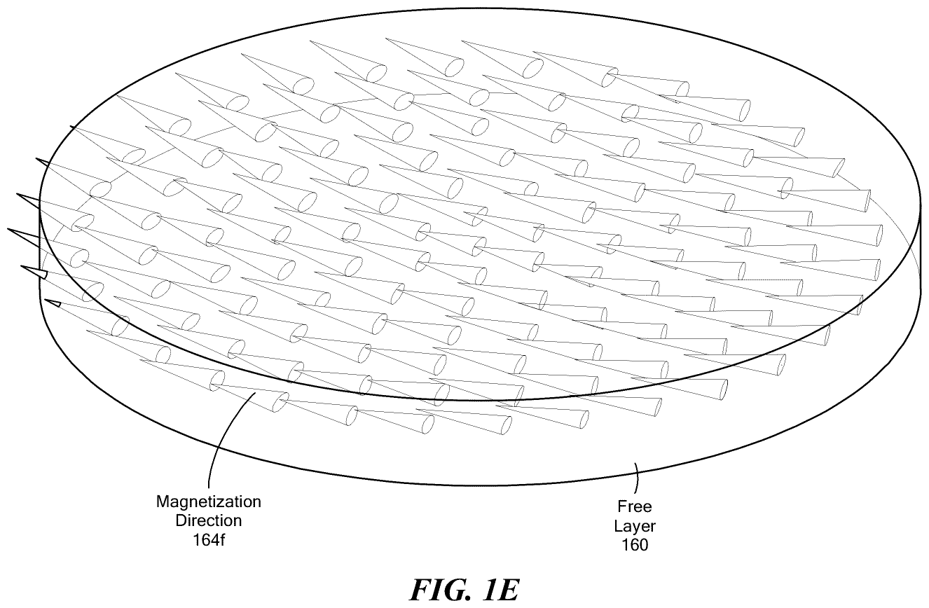

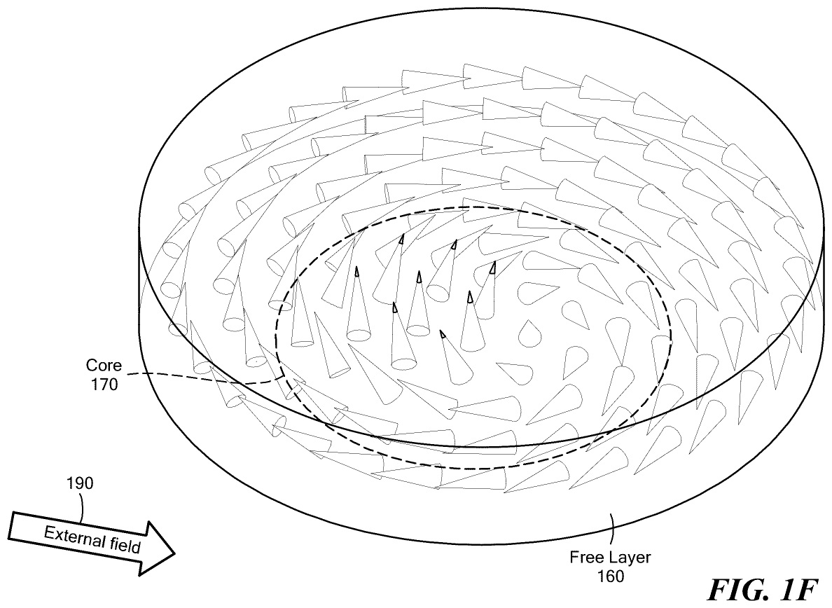

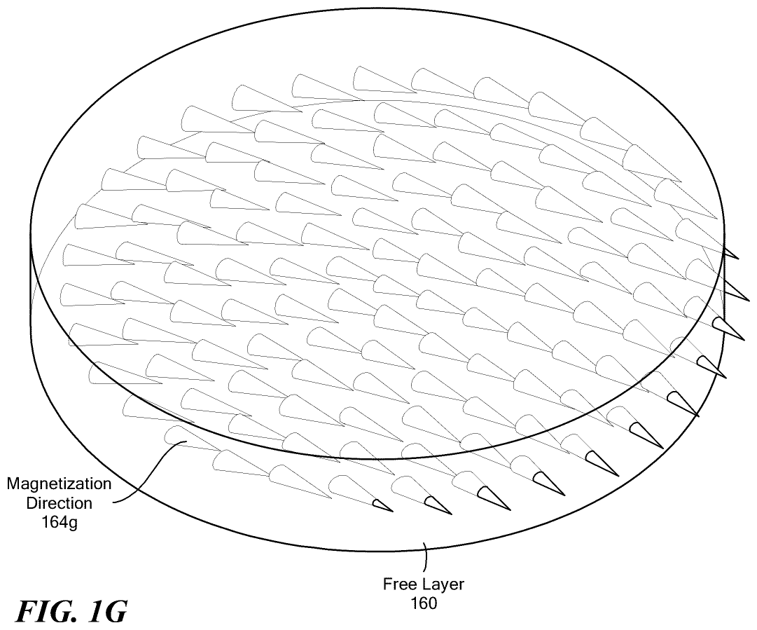

Referring to FIG. 1A, an illustrative TMR element 100 can have a stack 102 of layers 106, 110, 114, 118, 122, 126, 128, 132 indicative of one pillar of a multi-pillar TMR element. Generally, the layer 106 is a seed layer (e.g., a copper nickel (CuN) layer) with the layer 110 located on the seed layer 106. The layer 110 includes platinum manganese (PtMn) or iridium manganese (IrMn), for example. The layer 114 is located on the layer 110 and the layer 118 is located on the layer 114. In one example, the layer 114 includes cobalt iron (CoFe) and the layer 118 is a spacer layer and includes ruthenium (Ru). On the layer 118, a magnesium oxide (MgO) layer 126 is sandwiched between two cobalt iron boron (CoFeB) layers 122, 128. A cap layer 132 (e.g., tantalum (Ta)) is located on the CoFeB layer 128. The layer 114 is a single layer pinned layer that is magnetically coupled to the layer 110. The physical mechanism that is coupling layers 110 and 114 together is sometimes called an exchange bias.

A free layer 130 includes the CoFeB layer 128. In some examples, the free layer 130 may include an additional layer of nickel iron (NiFe) (not shown) and a thin layer of tantalum (not shown) between the CoFeB layer 128 and the NiFe layer.

Referring to FIG. 1B, a TMR formed as a pillar may include a free layer 160 that has a magnetic vortex. For example, the magnetic vortex has magnetization directions (e.g., a magnetization direction 164a, magnetization direction 164b, magnetization direction 164c, magnetization direction 164d) that loop around the free layer 160. The free layer 160 is a magnetic disk. An angle of the magnetization direction 164a with respect to a surface of the free layer 160 being about 0° at the outer edges of the free layer 160.

The magnetic vortex has a core 170 (sometimes called a “magnetic vortex core”). Closer to the center of the core 170, the magnetization directions start to become more and more non-planar the closer to the center of the core 170. That is, the angle of the magnetization direction with respect to the surface of the free layer 160 increases the closer to the center of the core 170 a magnetization direction is. For example, an angle of the magnetization direction 164b with respect to the surface of the free layer 160 is higher than the angle of the magnetization direction 164a with respect to the surface of the free layer 160, an angle of the magnetization direction 164c with respect to the surface of the free layer 160 is higher than the angle of the magnetization direction 164b with respect to the surface of the free layer 160, and an angle of the magnetization direction 164d with respect to the surface of the free layer 160 is higher than the angle of the magnetization direction 164c with respect to the surface of the free layer 160.

Exchange energy and demagnetizing energy are two key phenomena in magnetic disks. Exchange energy increases energy cost when the magnetization is not homogeneous across the magnetic material of the magnetic disk while the demagnetizing energy increases cost when the magnetization directions point outside of the magnetic disk. Exchange energy is a volume effect term while demagnetizing energy is an edge effect term.

Referring to FIG. 1C, when the magnetic disk of the free layer 160 has a large diameter and is thin, magnetization directions (e.g., a magnetization direction 164e) tend to be uniform and in the plane of the free layer 160 across the magnetic disk. There is a cost of demagnetizing energy as magnetization directions point outside the magnetic disk. This energy cost is located on the edges of the magnetic disk. Thus, if the magnetic disk has a large enough diameter, then the volume effect (i.e., exchange energy) is more important than an edge effect (i.e., demagnetizing energy). Therefore, it is less expensive to have the magnetization homogeneous in a plane.

Referring back to FIG. 1B, if the magnetic disk is not as wide in diameter and thicker than the magnetic disk in FIG. 1C, then the edge effect (i.e., demagnetizing energy) is more important than the volume effect (i.e., exchange energy), which enables the magnetization directions to curl inside the magnetic disk. Exchange energy prevents the singularity in the center, so that the magnetization directions point up or downward in the core 170 (e.g., magnetization directions 164c, 164d). The core 170 produces demagnetizing energy, but the demagnetizing energy is produced in a very limited area of the magnetic disk. In FIG. 1B, the size of the core 170 is exaggerated with respect to the free layer 160 to make it easier to be viewed and described herein.

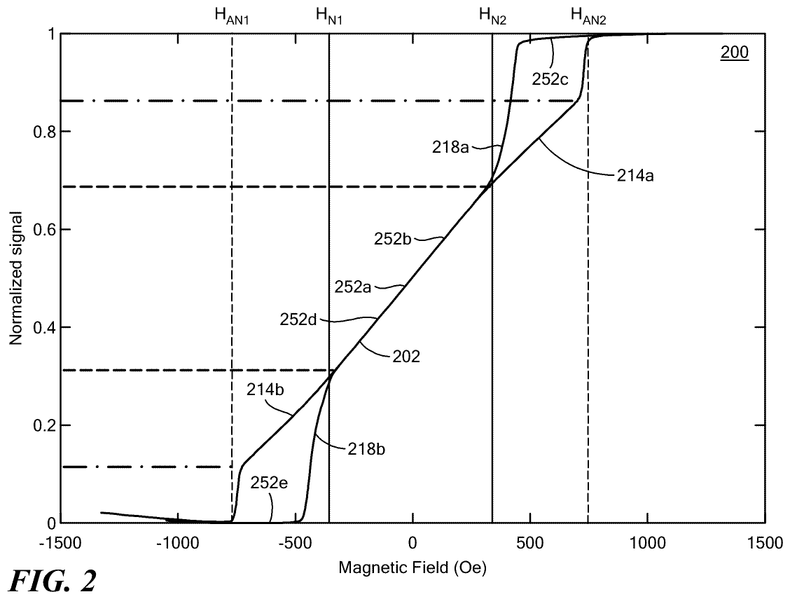

Referring to FIGS. 1D and 1E, when an external magnetic field 180 is applied to the free layer 160 that includes a magnetic vortex, the core 170 of the magnetic vortex moves to favor magnetization along the applied magnetic field 180. However, if the applied magnetic field 180 is too large, the core 170 is pushed out of the magnetic disk and the magnetization directions (e.g., magnetization direction 164e) in the magnetic disk becomes almost homogeneous. This is called vortex annihilation. The external magnetic field 180 must be decreased down to a nucleation magnetic field level before a vortex core can be nucleated inside the magnetic disk again as will be described with respect to FIG. 2.

Referring to FIGS. 1F and 1G, similarly, when an external magnetic field 190 is applied (opposite to the magnetic field 180) to the free layer 160 that includes a magnetic vortex, the core 170 of the magnetic vortex moves to favor magnetization along the applied magnetic field 190. However, if the applied magnetic field 180 is too large, the core 170 is pushed out of the magnetic disk and the magnetization directions (e.g., magnetization direction 164f) in the magnetic disk becomes homogeneous.

Referring to FIG. 2, a graph 200 depicts an example of a TMR signal response to changes in a detected magnetic field. Nucleation fields are denoted by H_{N1} and H_{N2}. Annihilation fields are denoted by H_{AN1} and H_{AN2}. A TMR signal response 202 is linear between H_{N1} and H_{N2}.

However, between H_{AN1} and H_{N1} and between H_{N2} and H_{AN2}, the TMR signal response 202 may be either linear or saturated. For example, the TMR signal response 202 between H_{N2} and H_{AN2} is linear along a portion 214a and saturated along the portion 218a, and the TMR signal response 202 between H_{N1} and H_{AN1} is linear along a portion 214b and saturated along the portion 218b.

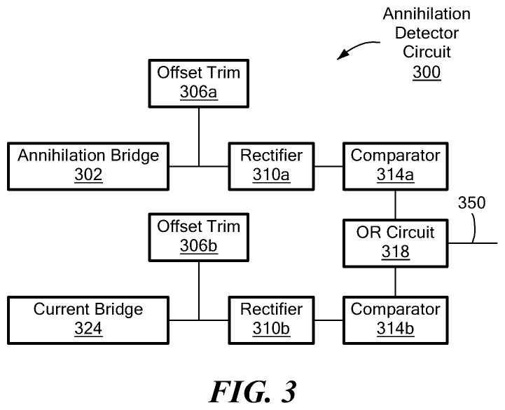

Saturation occurs when a magnetic vortex of TMR is exposed to a magnetic field that is higher than H_{AN1} Or H_{AN2} (i.e., the vortex is annihilated) and the TMR signal response 202 does not return to H_{N1} or H_{N2}, respectively. An annihilation detector as described herein (e.g., an annihilation detector 300 (FIG. 3)) can determine if an annihilated vortex exists in which case the TMR signal response 202 beyond H_{N1} and H_{N2} cannot be used. However, if the annihilation detector does not detect an annihilated vortex, then the TMR signal response 202 between H_{AN1} and H_{N1} and between H_{N2} and H_{AN2} may be used.

A point 252a on the TMR signal 202 response corresponds to the free layer 160 in FIG. 1B. A point 252b on the TMR signal 202 response corresponds to the free layer 160 in FIG. 1D, and a point 252c on the TMR signal 202 response corresponds to the free layer 160 in FIG. 1E. A point 252d on the TMR signal 202 response corresponds to the free layer 160 in FIG. 1F, and a point 252e on the TMR signal 202 response corresponds to the free layer 160 in FIG. 1G.

Referring to FIG. 3, an example of an annihilation detector that can detect an annihilation vortex is the annihilation detector 300. The annihilation detector 300 includes an annihilation bridge 302, offset trim circuits 306a, 306b, rectifiers 310a, 310b, comparators 314a, 314b, an OR circuit, and a current bridge 324.

An output of the annihilation bridge 302 is trimmed by the offset trim circuit 306a and then rectified by the rectifier 310a. The comparator 314a compares the rectified signal from the rectifier 310a with a first threshold value. In one example, if the rectified signal from the rectifier 310a is higher than the first threshold, then the vortex is annihilated. In one example, the first threshold is derived from a hysteresis curve.

An output of the current bridge 324 is trimmed by the offset trim circuit 306b and then rectified by the rectifier 310b. The comparator 314b compares the rectified signal from the rectifier 310b with a second threshold value. In one example, if the rectified signal from the rectifier 310b is higher than the second threshold, then the vortex is annihilated. In one example, the second threshold may be the current that corresponds to H_{AN1} and/or H_{AN2}.

The outputs of the comparator 314a, 314b are sent to the OR circuit 318. The OR circuit performs a logical “OR” function on the outputs of the comparator 314a, 314b to generate an output signal 350, which is an output for the annihilation detector 300.

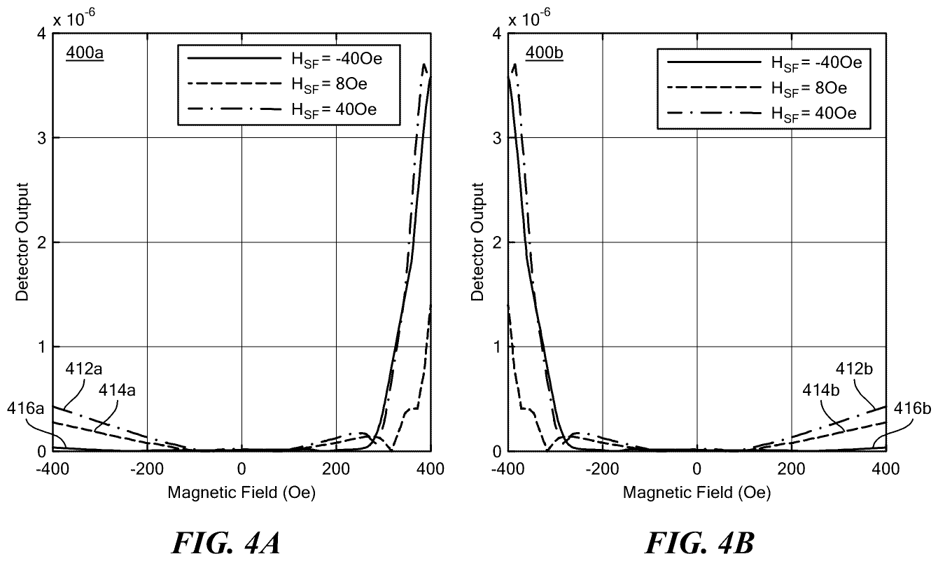

Referring to FIGS. 4A and 4B, graphs 400a, 400b are examples of the output signal 350 (FIG. 3) for different stray magnetic fields H_{SF}. The X-axis, for each graph 400a, 400b, is a magnetic field (i.e., signal of interest) generated from the conductor (e.g., the conductor 506), and the Y-axis, for each graph 400a, 400b, is the rectified output (in arbitrary units) of the annihilation detector 300. There are two graphs 400a, 400b because the annihilation of the vortex may happen either toward negative magnetic fields (graph 400b) or positive magnetic fields (400a). Curves 412a, 412b represent a stray magnetic field of 40 Oersted, curves 414a, 414b represent a stray magnetic field of 8 Oersted and Curves 412a, 412b represent a stray magnetic field of 40 Oersted.

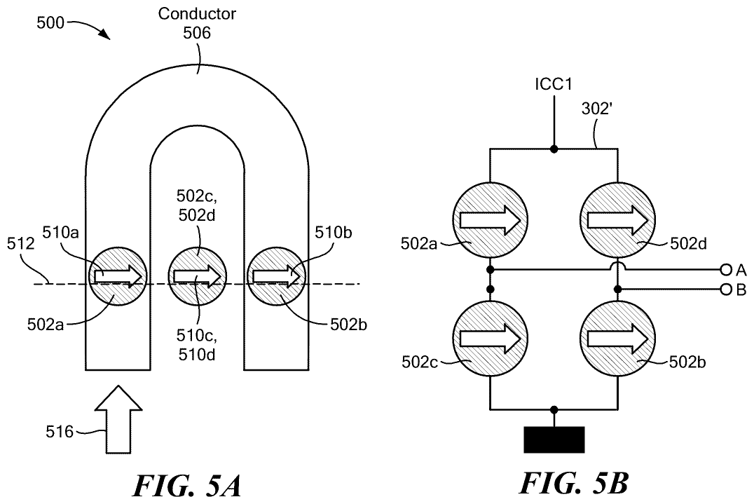

Referring to FIG. 5A, a current sensor configuration 500 includes TMR elements (e.g., a TMR element 502a, a TMR element 502b, a TMR element 502c and a TMR element 502d) and a one-turn conductor 506. The TMR elements 502a, 502b, 502c, 502d each includes at least one free layer with a magnetic vortex.

TMR elements 502a, 502b, 502c, 502d each include a reference direction that is the same direction as the other TMR elements. A reference direction is the direction that the magnetoresistance element is most sensitive to changes in a magnetic field. For example, a resistance of the magnetoresistance element changes the most for changes in the magnetic field in the reference direction. The TMR element 502a has a reference direction 510a, the TMR element 502b has a reference direction 510b, the TMR element 502c has a reference direction 510c, and the TMR element 502d has a reference direction 510d.

The TMR elements 502a, 502b are on top of the conductor 506 and the TMR elements 502c, 502d are disposed between the TMR elements 502a, 502b and not in contact with the conductor 506. In one example, TMR element 502c and the TMR element 502d may be interleaved. In one example, the TMR elements 502a, 502b may be separated from the conductor 506 by a distance between 50 and 200 microns.

The TMR elements 502a, 502b, 502c, 502d are on a plane 512 that extends into and out of FIG. 5A. During operation, a current 516 is applied to one end of the conductor 506 to form an Oersted field.

Since the TMR elements 502c, 502d are placed in the center of the one-turn conductor 506, TMR elements 502c, 502d are exposed only to a stray magnetic field H_{SF}, while the TMR elements 502a, 502b are exposed to both a stray magnetic field, H_{SF} and the Oersted field caused by the current I (e.g., current 516) through the conductor 506. In one example, the TMR element 502a detects a magnetic field H_{A}, the TMR element 502b detects a magnetic field H_{B}, the TMR element 502c detects a magnetic field H_{C}, and the TMR element 502d detects a magnetic field HD so that:

$$\begin{matrix}{H}_{A} = {H}_{SF} + α \cdot I , \\ {H}_{B} = {H}_{SF} - α \cdot I , \\ {H}_{C} = {H}_{D} = {H}_{SF}\end{matrix} ,$$

where a is a conversion factor from current to magnetic field.

Referring to FIG. 5B, an example of an annihilation bridge 302 is an annihilation bridge 302′. An output of the bridge 302′ is the difference between a signal measured at node A and a signal measured at node B.

In one example, with a current source ICC1, the signal measured at node A and the signal measured at node B are each voltage signals. In another example, if the current source ICC1 is replaced with a fixed voltage source and the voltages are fixed at node A and node B, then the signal measured at node A and the signal measured at node B are each current signals.

The TMR element 502a and the TMR element 502c are electrically connected in series to form a first leg of the bridge 302′. The TMR element 502a is electrically closer to the current source ICC1 than the TMR element 502c.

The TMR element 502b and the TMR element 502d are electrically connected in series to form a second leg of the bridge 302′. The TMR element 502d is electrically closer to the current source ICC1 than the TMR element 502b.

By connecting the TMR elements 502a, 502b, 502c, 502d in a bridge one can obtain a net magnetic field due to stray field and the Oersted field of:

$${H}_{C} + {H}_{D} - ( {H}_{A} + {H}_{B} ) = {H}_{SF} + {H}_{SF} - ( {H}_{SF} + α \cdot I + {H}_{SF} - α \cdot I ) = 0.$$

The signal is zero whatever the current or stray magnetic field are unless a vortex is annihilated because the magnetic field on one element is higher than HAN. Thus, the configuration in FIG. 5A reduces stray field signals unless one or more of the TMR elements 502a, 502b, 502c, 502d no longer has a linear response to a magnetic field (i.e., have one or more annihilated vortices).

Referring to FIG. 5C, an example of a current bridge 324 is a current bridge 324′. An output of the bridge 324′ is the difference between a signal measured at node C and a signal measured at node D.

In one example, with a current source ICC2, the signal measured at node C and the signal measured at node D are each voltage signals. In another example, if the current source ICC2 is replaced with a fixed voltage source and the voltages are fixed at node C and node D, then the signal measured at node C and the signal measured at node D are each current signals.

The TMR element 502a and the TMR element 502b are electrically connected in series to form a first leg of the bridge 324′. The TMR element 502a is electrically closer in series to the current source ICC2 than the TMR element 502b.

The TMR element 502b and the TMR element 502a are electrically connected in series to form a second leg of the bridge 324′. The TMR element 502b is electrically closer in series to the current source ICC2 than the TMR element 502b.

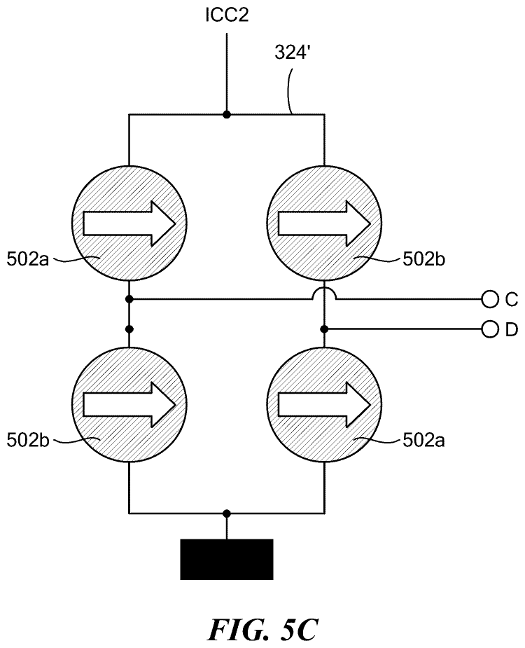

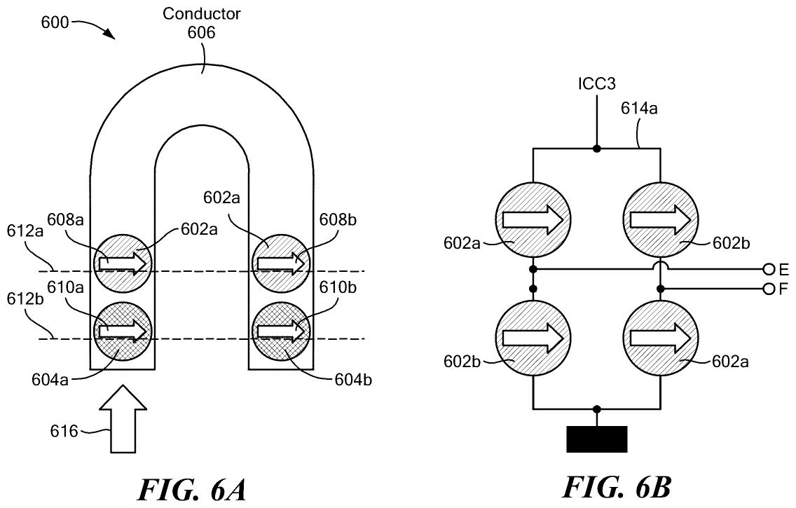

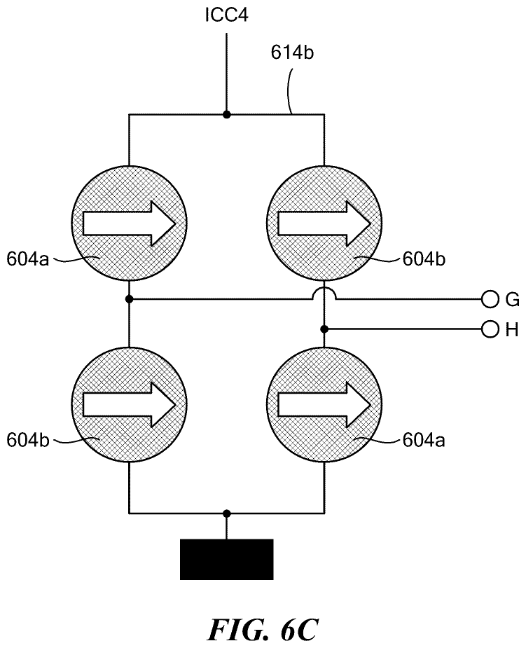

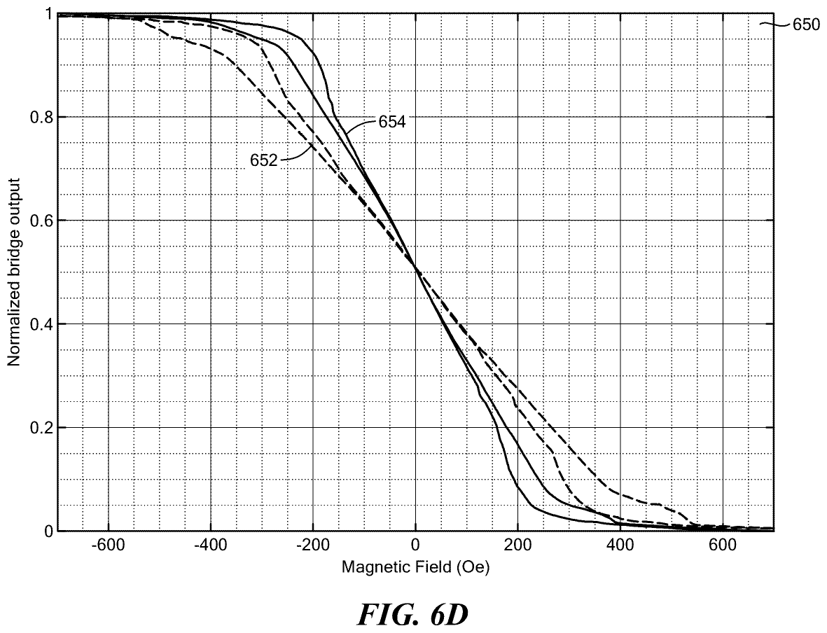

Referring to FIG. 6A, a current sensor configuration 600 includes TMR elements (e.g., a TMR element 602a, a TMR element 602b, a TMR element 604a and a TMR element 604b) and a one-turn conductor 606. The TMR elements 602a, 602b, 604a, 604b each includes a free layer with a magnetic vortex.

The TMR elements 602a, 602b are formed having pillars that have diameters that are smaller than pillars of TMR elements 604a, 604b. In one example, the TMR elements 602a, 602b are formed in pillars that have diameters of 2 microns, and the TMR elements 604a, 604b are formed in pillars that have diameters of 3 microns.

TMR elements 602a, 602b, 604a, 604b each include a reference direction that is the same direction as the other TMR elements. For example, the TMR element 602a has a reference direction 608a, the TMR element 602b has a reference direction 608b, the TMR element 604a has a reference direction 610a, and the TMR element 604b has a reference direction 610b.

The TMR elements 602a, 604a are on top of one end of the conductor 606 and the TMR elements disposed 602b, 604b are on top of the other end of the conductor 606. In one example, the TMR elements 602a, 602b, 604a, 604b may be separated from the conductor 606 by a distance between 50 and 200 microns.

The TMR elements 602a, 602b are on an axis 612a, and the TMR elements 604a, 604b are on an axis 612b. In one example, axis 612a is parallel to axis 612b. During operation, a current 616 is applied to one end of the conductor 606.

Referring to 6B, a bridge 614a includes TMR elements 602a, 602b. An output of the bridge 614a is the difference between a signal measured at node E and a signal measured at node F.

In one example, with a current source ICC3, the signal measured at node E and the signal measured at node F are each voltage signals. In another example, if the current source ICC3 is replaced with a fixed voltage source and the voltages are fixed at node E and node F, then the signal measured at node E and the signal measured at node F are each current signals.

The TMR element 602a and the TMR element 602b are electrically connected in series to form a first leg of the bridge 614a. The TMR element 602a is electrically closer in series to the current source ICC3 than the TMR element 602b.

The TMR element 602b and the TMR element 602a are electrically connected in series to form a second leg of the bridge 614a. The TMR element 602b is electrically closer in series to the current source ICC3 than the TMR element 602b.

A bridge 614b includes TMR elements 604a, 604b. An output of the bridge 614b is the difference between a signal measured at node G and a signal measured at node H.

In one example, with a current source ICC4, the signal measured at node G and the signal measured at node H are each voltage signals. In another example, if the current source ICC4 is replaced with a fixed voltage source and the voltages are fixed at node G and node H, then the signal measured at node G and the signal measured at node H are each current signals.

The TMR element 604a and the TMR element 604b are electrically connected in series to form a first leg of the bridge 614a. The TMR element 604a is electrically closer in series to the current source ICC4 than the TMR element 604b.

The TMR element 604b and the TMR element 604a are electrically connected in series to form a second leg of the bridge 614b. The TMR element 604b is electrically closer in series to the current source ICC4 than the TMR element 604b.

In one example, the bridge 614a and the bridge 614b are examples of current bridges each having different sensitivities to a magnetic field from one another and different inner ranges from one another. The bridge 614a has the largest linear range and is used as an example of the current bridge 324 (FIG. 3).

Referring to FIG. 6D, a graph 650 depicts a bridge output versus a magnetic field. For example, a curve 652 is an output of the bridge 614a (FIG. 6B) versus changes in the magnetic field, and a curve 654 is an output of the bridge 614b (FIG. 6B) versus changes in the magnetic field. An annihilation bridge such as the annihilation bridge 302′ (FIG. 5B) may be used to detect if the bridge 614a is annihilated or not. Bridge 614a provides a measurement of the magnetic field. Based on this measurement it is known whether bridge 614b is annihilated or not.

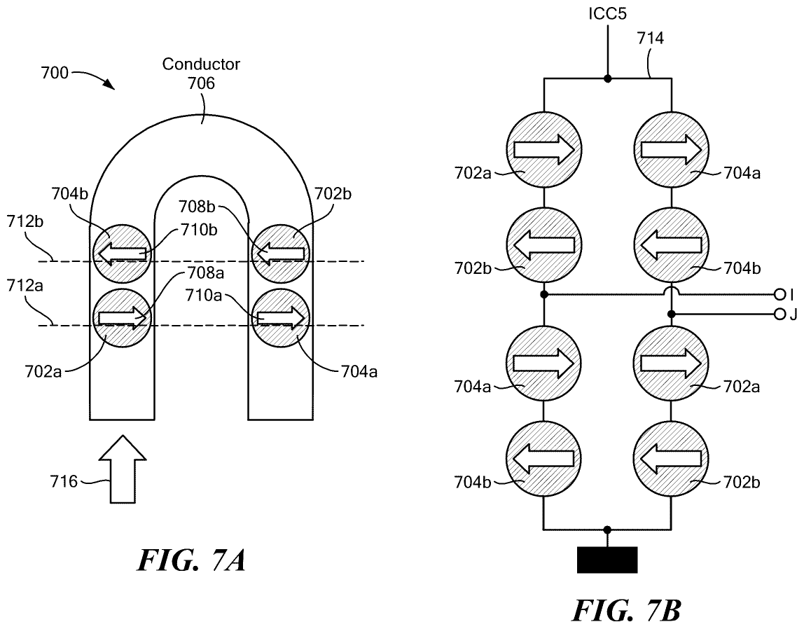

Referring to FIG. 7A, a current sensor configuration 700 includes TMR elements (e.g., a TMR element 702a, a TMR element 702b, a TMR element 704a and a TMR element 704b) and a one-turn conductor 706. The TMR elements 702a, 702b, 704a, 704b each includes a free layer with a magnetic vortex. The current sensor configuration 700 may be used to account for temperature gradients in an integrated circuit where some TMR elements are exposed to more temperature gradients than other TMR elements.

TMR elements 702a, 704a, each include a reference direction that is the same direction. For example, the TMR element 702a has a reference direction 708a, the TMR element 704a has a reference direction 710a that are in the direction.

TMR elements 702b, 704b, each include a reference direction that is the same direction. For example, the TMR element 704a has a reference direction 708b, and the TMR element 704b has a reference direction 710b that are in the direction. The reference directions 708b, 710b are in a direction 180° different from the reference directions 708a, 710a.

The TMR elements 702a, 704b are on top of one end of the conductor 706 and the TMR elements disposed 702b, 704a are on top of the other end of the conductor 706. In one example, the TMR elements 702a, 702b, 704a, 704b may be separated from the conductor 706 by a distance between 50 and 200 microns.

In one example, the TMR element 702a and the TMR element 704b are separated by no less than 20 microns±5 microns. In one example, the TMR element 704a and the TMR element 702b are generally separated by 400 microns±100 microns. During operation, a current 716 is applied to one end of the conductor 706.

In one example, the TMR elements 702a, 704a may be on an axis 712a, and the TMR elements 702b, 704b may be on an axis 712b. In one example, the axis 712a is parallel to the axis 712b.

Referring to FIG. 7B, a current bridge 714 includes TMR elements 702a, 702b, 704a, 704b. An output of the bridge 714 is the difference between a signal measured at node I and a signal measured at node J.

In one example, with a current source ICC5, the signal measured at node I and the signal measured at node J are each voltage signals. In another example, if the current source ICC5 is replaced with a fixed voltage source and the voltages are fixed at node I and node J, then the signal measured at node I and the signal measured at node J are each current signals.

The TMR element 702a, 702b, 704a, 704b are electrically connected in series to form a first leg of the bridge 714. In one example, the TMR element 702a is electrically closer in series to the current source ICC5 than the TMR element 702b, the TMR element 702b is electrically closer in series to a current source ICC5 than the TMR element 704a, and the TMR element 704a is electrically closer in series to a current source ICC5 than the TMR element 704b.

The TMR element 704a, 704b, 702a, 702b are electrically connected in series to form a second leg of the bridge 714. In one example, the TMR element 704a is electrically closer in series to a current source ICC5 than the TMR element 704b, the TMR element 704b is electrically closer in series to a current source ICC5 than the TMR element 702a, and the TMR element 702a is electrically closer in series to a current source ICC5 than the TMR element 702b.

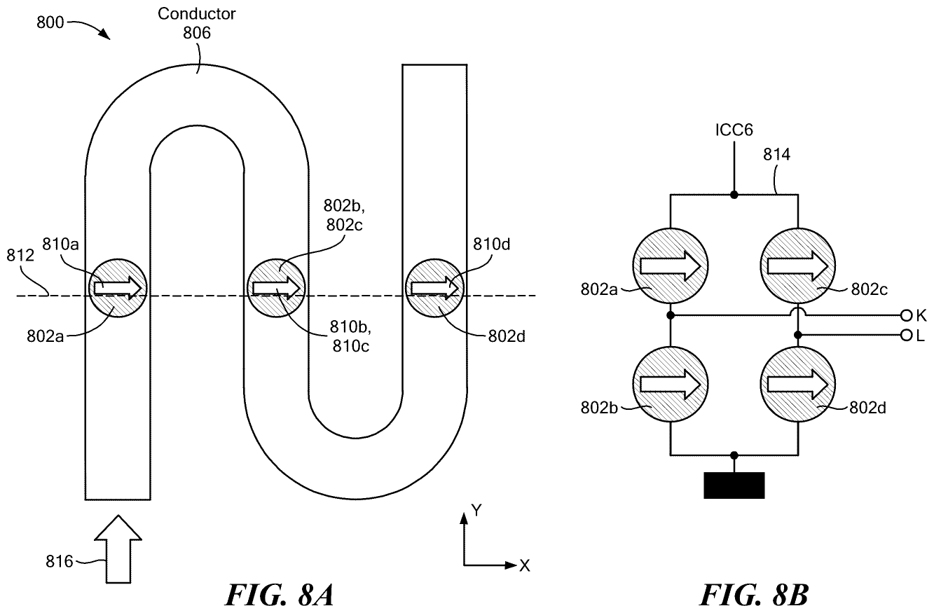

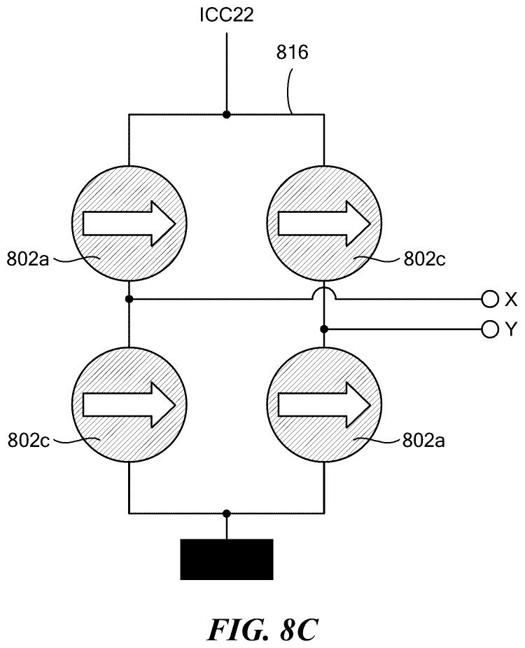

Referring to FIGS. 8A and 8B, a current sensor configuration 800 includes TMR elements (e.g., a TMR element 802a, a TMR element 802b, a TMR element 802c and a TMR element 802d) and a two-turn conductor 806. The TMR elements 802a, 802b, 802c, 802d each includes a free layer with a magnetic vortex.

TMR elements 802a, 802b, 802c, 802d each include a reference direction that is the same direction as the other TMR elements. For example, the TMR element 802a has a reference direction 810a, the TMR element 802b has a reference direction 810b, the TMR element 802c has a reference direction 810c, and the TMR element 802d has a reference direction 810d.

The TMR elements 802a, 802b, 802c, 802d are on top of the conductor 806. The TMR elements 802a, 802b, 802c, 802d are in the XY plane. During operation, a current 816 is applied to one end of the conductor 806. In one example, the TMR elements 802a, 802b, 802c, 802d may be separated from the conductor 606 by a distance between 50 and 200 microns.

The TMR element 802b is interleaved with the TMR element 802c. The distance between the TMR element 802a and the TMR element 802b is about the same as the distance between the TMR element 802b and the TMR 802d.

A bridge 814 includes TMR elements 802a, 802b, 802c, 802d. An output of the bridge 814 is the difference between a signal measured at node K and a signal measured at node L. In one example, the bridge 814 is an example of the current bridge 324 (FIG. 3).

In one example, with a current source ICC6, the signal measured at node K and the signal measured at node L are each voltage signals. In another example, if the current source ICC6 is replaced with a fixed voltage source and the voltages are fixed at node K and node L, then the signal measured at node K and the signal measured at node L are each current signals.

The TMR element 802a and the TMR element 802b are electrically connected in series to form a first leg of the bridge 814. The TMR element 802a is electrically closer in series to the current source ICC6 than the TMR element 802b.

The TMR element 802c and the TMR element 802d are electrically connected in series to form a second leg of the bridge 814. The TMR element 802c is electrically closer in series to the current source ICC6 than the TMR element 802d.

Referring to FIG. 8C, a bridge 816 includes TMR elements 802a, 802c. An output of the bridge 816 is the difference between a signal measured at node X and a signal measured at node Y. In one example, the bridge 816 is an example of the current bridge 324 (FIG. 3).

In one example, with a current source ICC22, the signal measured at node X and the signal measured at node Y are each voltage signals. In another example, if the current source ICC22 is replaced with a fixed voltage source and the voltages are fixed at node X and node Y, then the signal measured at node X and the signal measured at node Y are each current signals. The TMR element 802a and the TMR element 802c are electrically connected in series to form a first leg of the bridge 816. The TMR element 802a is electrically closer in series to the current source ICC22 than the TMR element 802c.

The TMR element 802c and the TMR element 802a are electrically connected in series to form a second leg of the bridge 816. The TMR element 802c is electrically closer in series to the current source ICC22 than the TMR element 802c.

In one example, the TMR element 802c may be replaced with the TMR element 802b in the bridge 816. In another example, the TMR element 802a may be replaced with the TMR element 802d in the bridge 816. In a further example, in the bridge 816, the TMR element 802c may be replaced with the TMR element 802b and the TMR element 802a may be replaced with the TMR element 802d.

In the current sensor configuration 800, common mode and gradient stray magnetic fields may be reduced along an X axis. Whatever the magnetic stray field distribution along the X axis, the magnetic stray field distribution can be decomposed in a Taylor series made of odd and even terms (where the TMR elements 802b, 802c are at X=0). In the following equations, only the common mode and the linear component are considered for simplicity. The signals coming from TMR elements 802a, 802b, 802c, 802d are, respectively, Sig_{A}, Sig_{B}, Sig_{C}, Sig_{D}, where:

$$\begin{matrix}{Sig}_{A} = Off + I \cdot {Sens}_{I} + α \cdot {H}_{0} - α \cdot δ x \cdot {H}_{1} \\ {Sig}_{B} = {Sig}_{C} = Off - I \cdot {Sens}_{I} + α \cdot {H}_{0} \\ {Sig}_{D} = Off = I \cdot {Sens}_{I} + α \cdot {H}_{0} + α \cdot δ x \cdot {H}_{1}\end{matrix}$$

and where:
Off is the base offset of the TMR element,
Sens_{I} is the sensitivity to the current flowing in the conductor 806,
I is the current flowing in the conductor 806,
α is the sensitivity to magnetic field,
H₀ and H₁ are respectively the common mode stray field and the linear gradient of stray field,
δx is the distance between the TMR element 802a and the TMR element 802b, which is equal to the distance between the TMR element 802b and the TMR element 802d.

An output of the bridge 814 or the difference of the current at the nodes I and J is:

$$\begin{matrix}Output = ( {Sig}_{B} + {Sig}_{C} ) - ( {Sig}_{A} + {Sig}_{D} ) \\ = ( 2 \cdot Off - 2 \cdot I \cdot {Sens}_{I} + 2 \cdot α \cdot {H}_{0} ) - \\ ( 2 \cdot Off + 2 \cdot I \cdot {Sens}_{I} + 2 \cdot α \cdot {H}_{0} - α \cdot δ x \cdot {H}_{1} + α \cdot δ x \cdot {H}_{1} ) \\ = - 4 I \cdot {Sens}_{I}\end{matrix}$$

By symmetry, the odd terms of the Taylor series are rejected, not just the linear gradient. Also, the differential bridge 816 rejects the even terms of the Taylor series of the stray field distribution (including common mode). So, depending on the stray field distribution symmetry, either the proposed construction or a simple differential field may be selected. In the case of current sensors, the stray magnetic field usually comes from adjacent current lines, so that the distribution of stray magnetic field is of the form 1/(x−x₀) where x₀ is the distance to the current line. In the current sensor configuration 800, most of the stray magnetic field is held in the common mode and linear gradient; so that the current sensor configuration 800 will reject a larger amount of the stray magnetic field.

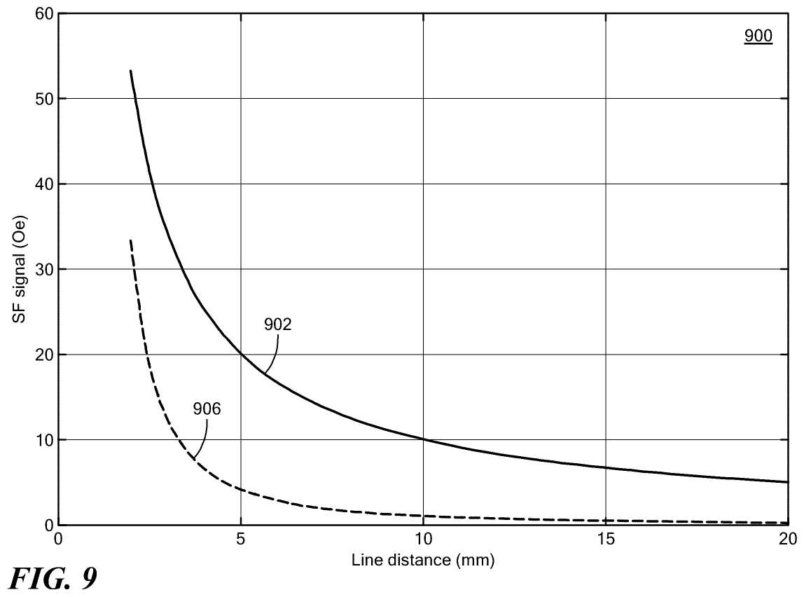

Referring to FIG. 9, a graph 900 depicts unrejected stray magnetic field versus line distance. The curve 902 depicts traditional techniques to fabricate a current sensor. A curve 906 depicts a current sensor using the current sensor configuration 800.

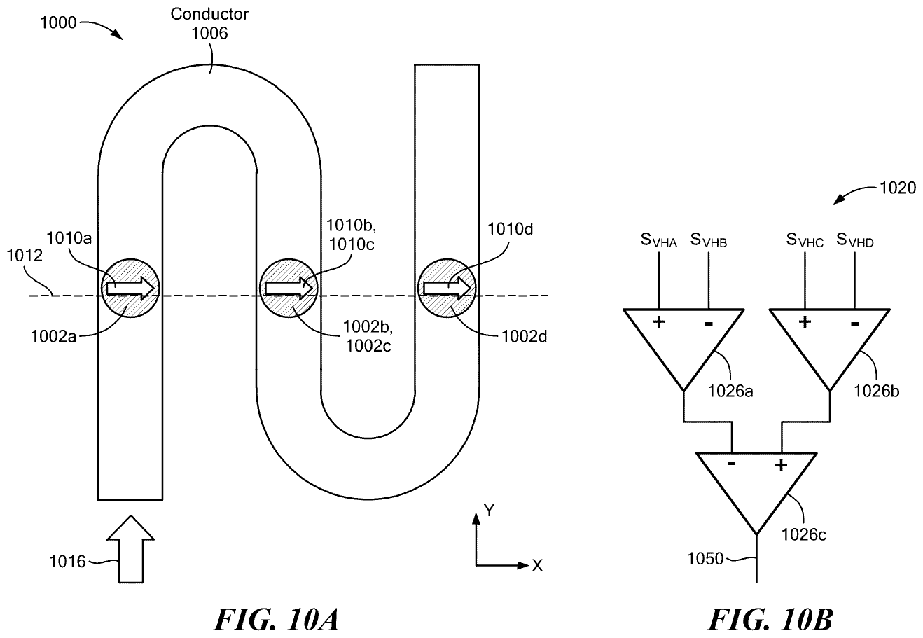

Referring to FIG. 10A, a current sensor configuration 1000 is another example of the current sensor configuration 800 but using vertical Hall elements. The current sensor includes vertical Hall elements (e.g., a vertical Hall element 1002a, a vertical Hall element 1002b, a vertical Hall element 1002c and a vertical Hall element 1002d) and a two-turn conductor 1006.

The vertical Hall elements 1002a, 1002b, 1002c, 1002d each include a reference direction that is the same direction as the other vertical Hall elements. For example, the vertical Hall element 1002a has a reference direction 1010a, the vertical Hall element 1002b has a reference direction 1010b, the vertical Hall element 1002c has a reference direction 1010c, and the vertical Hall element 1002d has a reference direction 1010d.

The vertical Hall elements 1002a, 1002b, 1002c, 1002d are on top of the conductor 1006. The vertical Hall elements 1002a, 1002b, 1002c, 1002d are on a plane 1012 that extends into and out of FIG. 10A. During operation, a current 1016 is applied to one end of the conductor 1006. In one example, the TMR elements 1002a, 1002b, 1002c, 1002d may be separated from the conductor 1006 by a distance between 50 and 200 microns.

The vertical Hall element 1002b is placed side-by-side with the vertical Hall element 1002c. The distance between the TMR element 1002a and the vertical Hall element 1002b is about the same as the distance between the vertical Hall element 1002b and the vertical Hall element 1002d.

Referring to FIG. 10B, a circuit 1020 processes the signals from the vertical Hall elements to reduce the stray magnetic fields. A signal S_{VHA} is an output signal of the vertical Hall element 1002a, a signal S_{VHB} is an output signal of the vertical Hall element 1002b, a signal S_{VHC} is an output signal of the vertical Hall element 1002c, and a signal S_{VHD} is the output signal of the vertical Hall element 1002d. The signal S_{PHB} is equal to the signal S_{VHC}.

The circuit 1020 includes a difference circuit 1026a, a difference circuit 1026b, and a difference circuit 1026c. The difference circuit 1026a takes the difference of signals S_{VHA} and S_{VHB} to produce an output signal equal to S_{VHA}−S_{VHB}. The difference circuit 1026b takes the difference of signals S_{VHC} and S_{VHD} to produce an output signal equal to S_{VHC}−S_{VHD}. The difference circuit 1026c takes the difference of signals S_{VHA}−S_{VHB} and S_{VHA}−S_{VHB} to produce an output signal 1050 equal to (S_{VHC}−S_{VHD})−(S_{VHA}−S_{VHB})=2S_{VHC}−S_{VHA}−S_{VHD}.

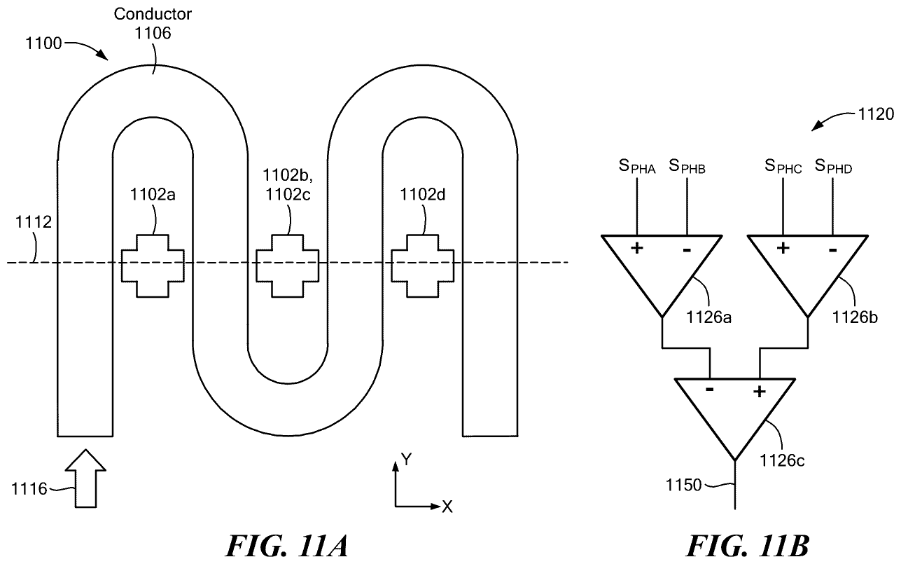

Referring to FIG. 11A, a current sensor configuration 1100 includes planar Hall elements (e.g., a planar Hall element 1102a, a planar Hall element 1102b, a planar Hall element 1102c and a planar Hall element 1102d) and a three-turn conductor 1106.

The planar Hall elements 1102a, 1102b, 1102c, 1102d are between the turns of the conductor 1106. The planar Hall elements 1102a, 1102b, 1102c, 1102d are on a plane 1112 that extends into and out of FIG. 11A. During operation, a current 1116 is applied to one end of the conductor 1106.

The planar Hall element 1102b is placed side-by-side with the planar Hall element 1102c. The distance between the TMR element 1102a and the planar Hall element 1102b is about the same as the distance between the planar Hall element 1102b and the planar Hall element 1102d.

Referring to FIG. 11B, a circuit 1120 processes the signals from the vertical Hall elements to reduce the stray magnetic fields. A signal S_{PHA} is an output signal of the vertical Hall element 1102a, a signal S_{PHB} is an output signal of the vertical Hall element 1102b, a signal S_{PHC} is an output signal of the vertical Hall element 1102c, and a signal S_{PHD} is the output signal of the vertical Hall element 1102d. The signal S_{PHB} is equal to the signal S_{PHC}.

The circuit 1120 includes a difference circuit 1126a, a difference circuit 1126b, and a difference circuit 1126c. The difference circuit 1126a takes the difference of signals S_{PHA} and S_{PHB} to produce an output signal equal to S_{PHA}−S_{PHB}. The difference circuit 1126b takes the difference of signals S_{PHC} and S_{PHD} to produce an output signal equal to S_{PHC}−S_{PHD}. The difference circuit 1126c takes the difference of signals S_{PHA}−S_{PHB} and S_{PHA}−S_{PHB} to produce an output signal 1150 equal to (S_{PHC}−S_{PHD})−(S_{PHA}−S_{PHB})=2S_{PHC}−S_{PHA}−S_{PHD}.

Having described embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A magnetic field current sensor comprising:
a conductor including a first turn, a second turn, and a third turn;
planar Hall elements including:
(i) a first planar Hall element generating a first signal, the first planar Hall element being disposed directly above or below a first region that is partially enclosed by the first turn,
(ii) a second planar Hall element generating a second signal, the second planar Hall element being disposed directly above or below a second region that is partially enclosed by the second turn,
(iii) a third planar Hall element generating a third signal, the third planar Hall element being disposed directly above or below the second region that is partially enclosed by the second turn, and
(iv) a fourth planar Hall element generating a fourth signal, the fourth planar Hall element being disposed directly above or below a third region that is partially enclosed by the third turn; and
circuitry that generates a difference signal indicative of twice the second signal less the first signal and less the fourth signal,
wherein the second planar Hall element is interleaved with the third planar Hall element,
wherein the second signal and the third signal are substantially equal,
wherein the first planar Hall element, the second planar Hall element, the third planar Hall element and the fourth planar Hall element are in a first plane, and
wherein a distance between the first planar Hall element and the second planar Hall element is equal to a distance between the second planar Hall element and the fourth planar Hall element.

2. The magnetic field current sensor of claim 1, wherein the planar Hall elements are disposed on a same side of the conductor.

3. The magnetic field current sensor of claim 1, wherein the first, second, and third turn are each U-shaped.

4. The magnetic field current sensor of claim 1, wherein the circuitry that generates the difference signal includes:
a first subtraction circuit that is arranged to generate a first subtraction signal which is indicative of a difference between the first signal and the second signal;
a second subtraction circuit that is arranged to generate a second subtraction signal which is indicative of a difference between the third signal and the fourth signal; and
a third subtraction circuit that is arranged to generate the difference signal based on a difference between the first subtraction signal and the second subtraction signal.

5. The magnetic field current sensor of claim 1, wherein the difference signal is indicative of a level of electrical current through the conductor.

6. A magnetic field current sensor comprising:
a two-turn conductor including a first turn and a second turn,
vertical Hall elements including:
(i) a first vertical Hall element generating a first signal, the first vertical Hall element being disposed directly above or below a first portion of the conductor that is part of the first turn only,
(ii) a second vertical Hall element generating a second signal, the second vertical Hall element being disposed directly above or below a second portion of the conductor that is part of both the first turn and the second turn,
(iii) a third vertical Hall element generating a third signal, the third vertical Hall element being disposed directly above or below the second portion of the conductor, and
(iv) a fourth vertical Hall element generating a fourth signal, the fourth vertical Hall element being disposed directly above or below a fourth portion of the conductor that is part of the second turn only; and
circuitry that generates a difference signal indicative of twice the second signal less the first signal and less the fourth signal,
wherein the second vertical Hall element is interleaved with the third vertical Hall element,
wherein the second signal and the third signal are substantially equal,
wherein the first vertical Hall element, the second vertical Hall element, the third vertical Hall element and the fourth vertical Hall element are in a first plane, and
wherein a distance between the first vertical Hall element and the second vertical Hall element is equal to a distance between the second vertical Hall element and the fourth vertical Hall element.

7. The magnetic field current sensor of claim 6, wherein the vertical Hall elements are disposed on a same side of the conductor.

8. The magnetic field current sensor of claim 6, wherein the first and second turn are each U-shaped.

9. The magnetic field current sensor of claim 6, wherein the circuitry that generates the difference signal includes:
a first subtraction circuit that is arranged to generate a first subtraction signal which is indicative of a difference between the first signal and the second signal;
a second subtraction circuit that is arranged to generate a second subtraction signal which is indicative of a difference between the third signal and the fourth signal; and
a third subtraction circuit that is arranged to generate the difference signal based on a difference between the first subtraction signal and the second subtraction signal.

10. The magnetic field current sensor of claim 6, wherein the difference signal is indicative of a level of electrical current through the conductor.

11. The magnetic field current sensor of claim 6, wherein the each of the first, second, third, and fourth vertical Hall elements is separated from the conductor by a distance between 50 and 200 microns.

12. A magnetic field current sensor comprising:
a conductor;
magnetic field sensing elements including a first magnetic field sensing element generating a first signal, a second magnetic field sensing element generating a second signal, a third magnetic field sensing element generating a third signal, and a fourth magnetic field sensing element generating a fourth signal;
circuitry that generates a difference signal indicative of twice the second signal less the first signal and less the fourth signal,
wherein the second magnetic field sensing element is interleaved with the third magnetic field sensing element,
wherein the second signal and the third signal are substantially equal, and
wherein a distance between the first magnetic field sensing element and the second magnetic field sensing element is equal to a distance between the second magnetic field sensing element and the fourth magnetic field sensing element.

13. The magnetic field current sensor of claim 12, wherein the magnetic field sensing elements are vertical Hall elements,
wherein the vertical Hall elements have a reference direction in a first direction,
wherein the conductor is a two-turn conductor, and
wherein the vertical Hall elements are in contact with the conductor.

14. The magnetic field current sensor of claim 12, wherein the magnetic field sensing elements are planar Hall elements,
wherein the conductor is a three-turn conductor, and
wherein the planar Hall elements are not in contact with the conductor.

15. The magnetic field current sensor of claim 12, wherein the first magnetic field sensing element, the second magnetic field sensing element, the third magnetic field sensing element, the third magnetic field sensing element, and the fourth magnetic field sensing element are each disposed directly above or below the conductor.

16. The magnetic field current sensor of claim 12, wherein the conductor includes three turns, the first magnetic field sensing element is disposed directly above or below a region that is partially enclosed by a first turn of the conductor, the second magnetic field sensing element and the third magnetic field sensing element are disposed directly above or below a region that is partially enclosed by a second turn of the conductor, and the fourth magnetic field sensing element is disposed directly above or below a region that is partially enclosed by a third turn of the conductor.

17. The magnetic field current sensor of claim 12, wherein the circuitry that generates the difference signal includes:
a first subtraction circuit that is arranged to generate a first subtraction signal which is indicative of a difference between the first signal and the second signal;
a second subtraction circuit that is arranged to generate a second subtraction signal which is indicative of a difference between the third signal and the fourth signal; and
a third subtraction circuit that is arranged to generate the difference signal based on a difference between the first subtraction signal and the second subtraction signal.

18. The magnetic field current sensor of claim 12, wherein the magnetic field sensing elements have a same reference direction.

19. The magnetic field current sensor of claim 12, wherein the conductor includes two or three turns.

20. The magnetic field current sensor of claim 12, wherein the magnetic field sensing elements are planar Hall elements.

21. The magnetic field current sensor of claim 12, wherein the first magnetic field sensing element, the second magnetic field sensing element, the third magnetic field sensing element and the fourth magnetic field sensing element are in a first plane.

22. The magnetic field current sensor of claim 12, wherein the each of the first, second, third, and fourth magnetic field sensing elements is separated from the conductor by a distance between 50 and 200 microns.
